(19) United States
(12) Patent Application Publication
(10) Pub. No.: US 2007/0062723 A1
(43) Pub. Date: Mar. 22, 2007

(54) Method of forming circuit pattern on printed circuit board

(75) Inventors: Young-Jae Kim, Suwon-si (KR); Jae-Woo Joung, Suwon-si (KR); Young-Seuck Yoo, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/514,079

(22) Filed: Sep. 1, 2006

(30) Foreign Application Priority Data
Sep. 2, 2005 (KR) 10-2005-0081578

(51) Int. Cl. H05K 1/03

(52) U.S. Cl. 174/255

(57) ABSTRACT

A method of forming circuit patterns on a printed circuit board is disclosed. The method of forming circuit patterns on a printed circuit board comprising: (a) applying etchant on portions of an insulation substrate where the circuit patterns are to be formed, (b) curing the etchant by adjusting curing conditions, (c) applying metal ink on the etched circuit patterns, and (d) sintering the metal ink, allows a great reduction in production costs, since the processes of applying photoresist (PR), exposing, and developing can be eliminated to simplify the overall process, and the circuit patterns of printed circuit boards can be formed minutely and with precision with a fewer number of processes and less time.

### CROSS-REFERENCE TO RELATED APPLICATIONS

This application claims the benefit of Korean Patent Application No. 2005-0081578 filed with the Korean Intellectual Property Office on Sep. 2, 2005, the disclosure of which is incorporated herein by reference in its entirety.

### BACKGROUND

1. Technical Field

The present invention relates to a method of forming circuit patterns, and in particular, to a method of forming circuit patterns on a printed circuit board.

2. Description of the Related Art

The circuit patterns of a printed circuit board are generally formed by performing on an insulation substrate the processes of copper plating, applying photoresist (PR), exposing, developing, and etching, etc. Meanwhile, with the recent trends towards smaller sizes and more functionalities in electronic products, there is a demand also for chip components having smaller sizes and more functionalities, along with a demand for lowered production costs. This requires technical improvements in the processes of forming circuit patterns on printed circuit boards.

Drawings (a) to (f) of FIG. 1 form a flow diagram illustrating the process of forming circuit patterns on a printed circuit board according to prior art. In describing the conventional process with reference to FIG. 1, the base material 1 for producing a printed circuit board comprises a metal layer 5, 5′ on each of the upper and lower surfaces of an insulation layer 3.

To form circuit patterns on this base material 1, etching resist 6, 6′ is applied on the surfaces of the metal layers 5, 5′; protective films 7, 7′ are formed on the surfaces of the etching resist 6, 6′; and then circuit films 8, 8′ are stacked on the surfaces of the protective films 7, 7′.

There are non-transmissive portions 9 formed on the circuit films 8, 8′. The non-transmissive portions 9 are portions through which light cannot penetrate, while the remaining portions besides the non-transmissive portions 9 are portions through which light can penetrate and have the same shape as the circuit patterns to be formed on the printed circuit board. The non-transmissive portions 9 are formed based on a given set of design plans for the circuit patterns using CAD/CAM operations.

Following the stacking of the circuit films 8, 8′ is the exposing. That is, when ultraviolet rays are irradiated onto the upper and lower surfaces of the base material as illustrated in (b) of FIG. 1, light is not irradiated onto the etching resist 6, 6′ applied on the positions corresponding to the non-transmissive portions 9, while light is irradiated onto the remaining portions. Thus, the etching resist 6, 6′ of the portions with irradiation are hardened, while the portions without irradiation maintain their original state.

Next, the circuit films 8, 8′ and protective films 7, 7′ are removed. This state with the films removed is as illustrated in (c) of FIG. 1. In (c) of FIG. 1, the etching resist 6, 6′ of the positions corresponding to the non-transmissive portions 9 is in its original state without hardening, while the etching resist 6, 6′ of the portions with the irradiation of light is in a hardened state.

Next, the base material 1 with the films removed is immersed in a developing liquid to proceed with the developing procedure. When the base material 1 is immersed in the developing liquid, the hardened etching resist 6, 6′ is not removed but remains on the base material 1, while the non-hardened portions of the etching resist 6, 6′ are removed to reveal the metal layers 5, 5′. This state in which the developing procedure has been completed is as illustrated in (d) of FIG. 1.

The above process is an example of a “negative type” using negative film, and an opposite form of a “positive type” may also be used, in which the portions undergoing irradiation are not hardened but are disintegrated, while the portions without irradiation are hardened and remain as resist.

Next, the base material 1 for which the developing procedure has been completed is immersed in an etchant. When the base material 1 is immersed in the etchant, the metal layers 5, 5′ of the portions with etching resist 6, 6′ remaining are maintained intact, whereas the portions of the metal layers 5, 5′ which are revealed due to the removed etching resist 6, 6′ are removed to reveal the inner insulation layer 3. This is as illustrated in (e) of FIG. 1.

Here, the remaining portions of the metal layers 5, 5′ that are not removed form the circuit patterns, and the circuit patterns C are completed when the etching resist 6, 6′ remaining on the surfaces of the metal layers 5, 5′ are removed to reveal the metal layers 5, 5′. This is as illustrated in (f) of FIG. 1.

After the forming of the circuit patterns C is complete, the printed circuit board is produced through processes such as applying PSR (photo solder resist), etc. Meanwhile, when forming a printed circuit board consisting of multiple layers, new insulation layers and metal layers are formed by plating, and the above procedures are repeated.

However, the method of forming the circuit patterns of a printed circuit board according to prior art entails the following drawbacks.

First, in performing exposure selectively for the etching resist 6, 6′, circuit films 8, 8′ known as photo masks must be used. However, as various procedures are performed with the circuit films 8, 8′ attached to the base material 1, deformations may occur in the dimensions of the circuit films 8, 8′ according to the working conditions such as temperature and humidity, etc. These deformations in dimensions incur reduced precision in the circuit patterns formed on the printed circuit board.

Second, the design procedures become more complicated, as the design of the protective films 7, 7′ and base material 1 must take into account both deformations in dimensions of the circuit films 8, 8′ and deformations in dimensions of the base material 1 according to the working conditions. Although in some cases glass substrates are used as alternative materials for the protective films 7, 7′ to avoid the deformations in dimensions of the protective films 7, 7′, there are difficulties in using glass substrates as they are inconvenient in handling and expensive in cost.

Meanwhile, a previous invention was proposed relating to a method of forming circuit patterns using inkjet printing, to address the above-mentioned problems of prior art in forming circuit patterns of a printed circuit board, in which the insulation substrate is partially removed by a laser beam in accordance with the wiring patterns of conductive circuits, and the circuits are formed by an inkjet technique on the removed portions. This, however, requires the addition of laser equipment and laser processes.

There is also an invention comprising the steps of forming adhesion layers using adhesive tape, forming wiring patterns on the layers by a droplet ejection method, and afterwards forming the circuits by blow-drying. However, since inkjet printing is used, the process of forming the wiring patterns must be performed several times to obtain the required thickness of the circuit patterns, and during this process, there is a risk of errors occurring in the circuit patterns such as unevenness and short-circuiting.

### SUMMARY

The present invention aims to provide a method of forming circuit patterns on a printed circuit board which simplifies the process of forming circuit patterns, provides the required thickness of the circuit patterns easily and inexpensively, and allows the forming of circuit patterns with greater precision.

One aspect of the invention provides a method of forming circuit patterns on a printed circuit board comprising: (a) applying etchant on portions of an insulation substrate, where the circuit patterns are to be formed, (b) curing the etchant by adjusting curing conditions, (c) applying metal ink in the etched circuit patterns, and (d) sintering the metal ink.

Operation (a) or operation (c) may preferably be performed by inkjet printing. Preferably, the insulation substrate may be a polyimide substrate, and the etchant may be an etchant for polyimide resin. The sintering conditions may include temperature and time. It may be preferable that the metal ink include metal particles of 1 nm to 100 nm in size.

Also provided is a printed circuit board comprising: an insulation substrate, a trench formed on a surface of the insulation substrate in correspondence with a portion where a circuit pattern is to be formed, and a conductive layer filled in the trench and forming the circuit pattern, wherein the trench is formed by etching, and the conductive layer is formed by sintering metal ink.

The trench may preferably be formed by printing etchant on the insulation substrate by inkjet printing and afterwards curing the etchant by adjusting curing conditions. The conductive layer may preferably be formed by filling metal ink in the trench by inkjet printing and afterwards drying and sintering.

It may be preferable that the insulation substrate be a polyimide substrate, and that the etchant be an etchant for polyimide resin. The metal ink may include metal particles of 1 nm to 100 nm in size. The depth of the trench may preferably be greater than or equal to 10 μm and lower than or equal to the thickness of the insulation substrate.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating the process of forming circuit patterns on a printed circuit board according to prior art.

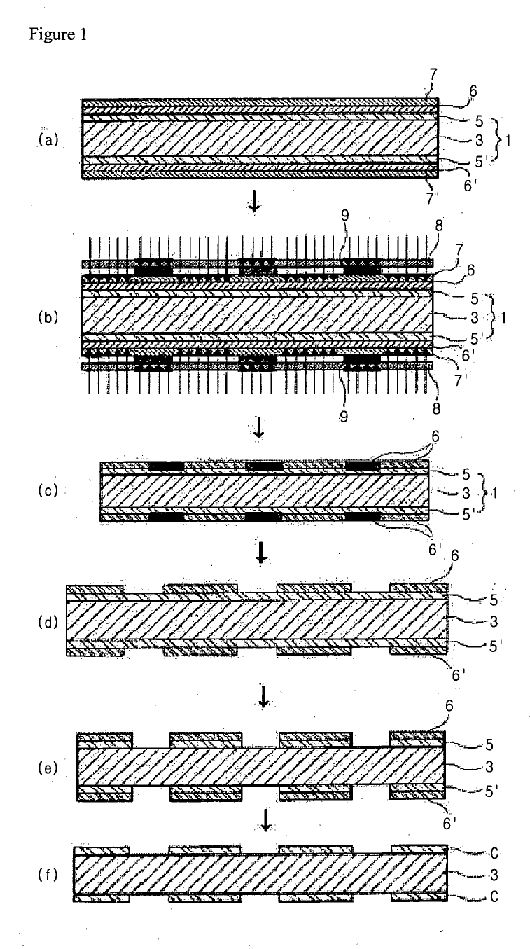

FIG. 2 is a flowchart illustrating the process of forming circuit patterns on a printed circuit board according to an embodiment of the present invention.

FIG. 3 is a flow diagram illustrating the process of forming circuit patterns on a printed circuit board according to an embodiment of the present invention.

### DETAILED DESCRIPTION

Hereinafter, embodiments of the invention will be described in more detail with reference to the accompanying drawings. In the description with reference to the accompanying drawings, those components are rendered the same reference number that are the same or are in correspondence regardless of the figure number, and redundant explanations are omitted.

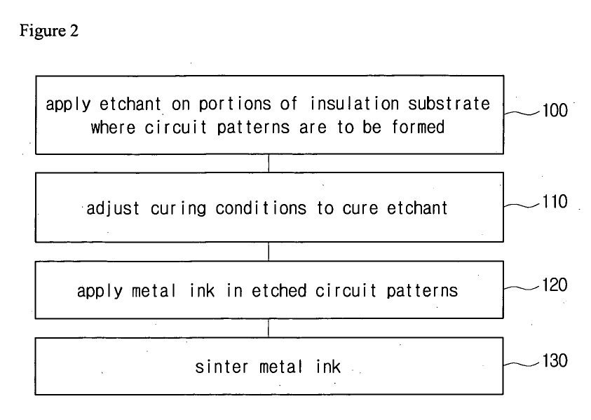

FIG. 2 is a flowchart illustrating the process of forming circuit patterns on a printed circuit board according to an embodiment of the present invention.

The present invention is characterized by a method of forming circuit patterns on a printed circuit board, in which processes such as plating, exposing, and etching, etc., typical of the highly time-consuming and expensive process of forming circuit patterns, are eliminated, and in which the circuit patterns are formed by ejecting etchant and metal ink according to inkjet printing methods, to allow microscopic patterns and enable adjustment of the pattern width.

To this end, first, etchant is applied (100) on portions of the insulation substrate, i.e. the base material of the printed circuit board, where the circuit patterns are to be formed. In contrast to prior art in which the circuit patterns are formed by plating the insulation substrate with copper laminate, etc., and then etching certain portions afterwards, the present invention is characterized by forming the circuit patterns directly on the insulation substrate, with portions where the circuit patterns are to be formed etched before applying the metal ink to obtain the required thickness of the circuit patterns.

While a polyimide substrate is generally used as the insulation substrate, the present invention is not thus limited, and other types of insulation substrate may also be used within a scope apparent to those skilled in the art.

As in prior art, the circuit patterns are based on a given set of design plans, and the etchant is applied in accordance with the circuit patterns within a scope apparent to those skilled in the art. However, since the circuit patterns in embodiments of the invention are formed by applying metal ink by inkjet printing, as will be described below, it is preferable that the etchant also be applied by inkjet printing. In this case, if the etchant is applied using an inkjet printing device, the etchant may be printed in accordance with the circuit patterns directly on the insulation substrate in conjunction with CAD/CAM software used in designing the circuit patterns, without a separate procedure for forming masks, to maximize the efficiency of the procedures.

As the etchant applied for the circuit patterns etch portions of the insulation substrate to form trenches where the metal ink is to be printed, an appropriate etchant must be used which is capable of etching in correspondence with the material of the insulation substrate. Thus, when a polyimide substrate is used as the insulation substrate, as mentioned above, an etchant for polyimide resin may desirably be used, while for an insulation substrate of another material, an etchant may desirably be used which is capable of etching correspondingly.

As the polyimide substrate is not only an insulation substrate but is also a base material high in durability and corrosion-resistance for providing stability to the printed circuit board, it is relatively more difficult to etch than substrates of other materials. Therefore, when using a polyimide substrate as the insulation substrate in an embodiment of the invention, careful attention is required in selecting the etchant. Any known product may be used as the etchant for polyimide resin within a scope apparent to those skilled in the art, and detailed descriptions will not be provided on the chemical composition and chemical structure, etc., of the etchant.

Next, the curing conditions are adjusted to cure the etchant (110). The insulation substrate becomes etched as etchant is applied on the insulation substrate and then cured under the appropriate conditions. Since, in order to obtain the required thickness of the circuit patterns, correspondingly etched trenches must be formed in the insulation substrate, the curing conditions are adjusted in accordance with the material of the insulation substrate and the properties of the etchant, in such a manner as to form trenches etched to have an appropriate thickness.

The curing conditions typically concern temperature and time, and it is desirable to obtain data beforehand on the temperature or time for etching a particular amount of thickness in relation to the material of the insulation substrate and the characteristics of the etchant selected accordingly. In embodiments of the present invention, data on the curing conditions, i.e. temperature or time, may be supplied by the etchant manufacturer, or may be collected beforehand through a set of experiments.

Next, metal ink is applied (120) in the circuit patterns etched on the insulation substrate due to the curing of the etchant. As described above, the etched circuit patterns are obtained, by the etching of the insulation substrate, in the form of trenches of a depth corresponding to the required thickness of the circuit patterns. Therefore, to obtain the required thickness of the circuit patterns by applying the metal ink in the etched circuit patterns, it is desirable that the applying be such that fills up the etched trenches with the metal ink.

If the etched trenches are not filled up with the metal ink, the required thickness of the circuit patterns may not be obtained, and if they are overfilled with the metal ink, there is overflow of the metal ink on the surface of the insulation substrate, to create a risk of short-circuits in the circuit patterns, and of problems in the stacking process in the case of a multi-layered printed circuit board.

Filling up the circuit patterns with the metal ink is performed, as in prior art, based on a given set of design plans, as metal ink is applied in accordance with the circuit patterns within a scope apparent to those skilled in the art. However, it may be more preferable that the metal ink be applied by inkjet printing, as for the case of the etchant.

In this case, as with the case of the etchant, if the metal ink is applied using an inkjet printing device, the metal ink may be printed in accordance with the circuit patterns directly on the insulation substrate in conjunction with CAD/CAM software used in designing the circuit patterns, without a separate procedure for forming masks. Moreover, if the inkjet head is configured to be capable of using the etchant and the metal ink concurrently, the printing of the etchant and the metal ink may be performed using a single inkjet printing device to maximize the efficiency of the procedures.

When applying the etchant and metal ink both by inkjet printing, the circuit patterns of the printed circuit board may be formed with great convenience, using a single printing device and a conjunctive CAD/CAM software program.

Meanwhile, when using inkjet printing, in order to fill the metal ink in the trenches, formed by etching on the insulation substrate in accordance with the circuit patterns, as described above, the amount of metal ink ejected from the inkjet head must be adjusted in correspondence with the depth of the trenches. To this end, the printing speed of the head, size of the nozzles, and ink ejection pressure, etc., are controlled. Controlling the amount of ink ejected is apparent to those skilled in the art, and detailed descriptions will not be provided on this matter.

For the metal ink ejected during inkjet printing, an ink is used which contains microscopic metal particles having sizes in the nano scale. This is for allowing the ink to be carried in an ink chamber of the inkjet head and sprayed through nozzles in a stable manner, and the sizes of the metal particles contained in the metal ink is preferably about 1 nm to 100 nm. However, the sizes of the metal particles contained in the metal ink according to embodiments of the invention are not limited to the numerical range mentioned above, and it is to be appreciated that metal ink containing metal particles of other sizes may also be used within a scope apparent to those skilled in the art.

Finally, the metal ink is sintered (130), i.e. dried and fired, to complete the circuit patterns (130). Since the metal ink is typically a liquid, the applied metal ink must be completely dried and fired in forming the circuit patterns on the insulation substrate, for which it is desirable that the metal ink printed on the printed circuit board be sintered under appropriate conditions.

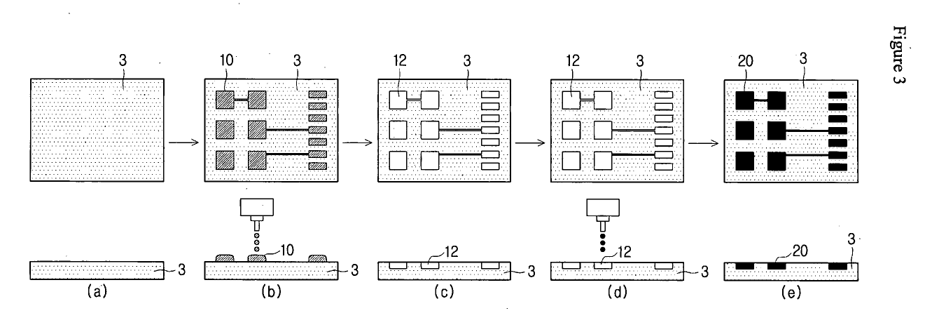

FIG. 3 is a flow diagram illustrating the process of forming circuit patterns on a printed circuit board according to an embodiment of the present invention. In FIG. 3 are illustrated an insulation substrate 3, etchant 10, trenches 12, and metal ink 20.

A process of forming circuit patterns on a printed circuit board according to an embodiment of the invention will be described below in detail with reference to FIG. 3.

The first step is to prepare the insulation substrate 3, as in (a) of FIG. 3. In contrast to prior art, embodiments of the present invention involve eliminating such processes as applying photoresist (PR), exposing, and developing, etc., and involve forming the circuit patterns directly on the surface of an insulation substrate 3, such as a polyimide substrate, using an inkjet printer. Thus, the process of forming circuit patterns may begin with only the insulation substrate 3, without the need for a substrate plated with a metal layer, such as a copper clad laminate (CCL), etc.

The second step is to apply an etchant 10 in correspondence with the material of the insulation substrate 3, as illustrated in (b) of FIG. 3. The etchant 10 is selected from within a range that allows the etching of the insulation substrate 3. In step 2, the etchant 10 is applied by printing the etchant 10 for the insulation substrate 3 using an inkjet printer on portions corresponding to the circuit patterns.

That is, the etchant 10 is selectively applied onto the surface of the insulation substrate 3, i.e. the base material of the printed circuit board. For this, the etchant 10 is selectively printed, i.e. in the form of the circuit patterns, directly on the surface of the insulation substrate 3, using a printing device which has received various data, such as the size, area, and shape, etc., of the circuit patterns, from a CAD system.

The third step is to cure the applied etchant 10, as illustrated in (c) of FIG. 3, such that etching is performed to a particular depth from the surface of the insulation substrate 3. By thus applying the etchant 10 on the surface of the insulation substrate 3 and curing, trenches 12 are formed on the insulation substrate 3 due to the etching, where the required thickness of the circuit patterns may be obtained when the etching depth of the trenches 12 are adjusted and the metal ink 20 is filled therein.

Appropriate curing conditions are necessary in etching the insulation substrate 3 to a required depth, and a desired etch ed form is obtained typically by adjusting the temperature and time of the etching.

By thus applying the etchant 10 on the insulation substrate 3 and curing, the portions of the insulation substrate 3 where the etchant 10 is applied are removed to produce the shape of trenches 12, as illustrated in (c) of FIG. 3.

Also, whereas the surfaces of the insulation substrate 3 is smooth, the surfaces of the trenches 12 formed due to the etching have a degree of roughness, whereby an additional effect may be obtained of surface improvement for increasing the adhesion between the wiring formed by the metal ink 20 filled in the trenches 12 and the insulation substrate 3.

The fourth step is to apply the metal ink 20 in the etched trenches 12, as illustrated in (d) of FIG. 3. Here, to apply the metal ink 20 using an inkjet printing device, a metal ink 20 containing metal particles of sizes in the nano scale is used, and after filling the ink chamber of the inkjet head with the metal ink 20, a printing device such as an inkjet printer is used to print into the etched trench 12 portions (circuit patterns).

The etchant 10 of the first step described above and the metal ink 20 of the fourth step are printed using an inkjet printing device after receiving data on the pre-designed circuit patterns from a CAD system. After printing the metal ink 20, the drying and firing processes are performed, as illustrated in (e) of FIG. 3, to complete the circuit patterns of the printed circuit board.

Meanwhile, to apply a method of forming patterned circuits based on an embodiment of the invention to manufacturing a multi-layered printed circuit board, one needs simply to repeat the above processes for each layer and continuously stack the layers.

The method of forming circuit patterns on a printed circuit board according to an embodiment of the present invention allows the forming of circuit patterns through a very simple process by securing the positions where the circuit patters are to be formed through direct etching, without the developing and exposing processes of prior art, and forming the circuit patterns thereon.

That is, an appropriate etchant 10 is selectively printed for etching on the surface of the insulation substrate 3, i.e. the base material of the printed circuit board, and then metal ink 20 is filled in the etched portions to complete the circuit patterns, so that among the processes for forming circuit patterns according to prior art, the processes of applying photoresist (PR), exposing, and developing, as well as supplementary processes for proceeding with such processes, may be eliminated.

In addition, the present invention relates to a printed circuit board, as illustrated in (e) of FIG. 3, comprising an insulation substrate 3, trenches 12 formed on the surface of the insulation substrate 3, and a conductive layer filled in the trenches 12.

The trenches 12 are portions sunken in from the surface of the insulation substrate 3 by a predetermined depth in correspondence with the portions where the circuit patterns are to be formed. Conductive material is filled into the trenches 12 to form circuit patterns of a required thickness.

While the trenches 12 may be formed by various methods within a scope apparent to those skilled in the art, it is preferable that they be formed by applying etchant 10 on the surface of the insulation substrate 3 and curing. When forming the trenches 12 by etching, the trenches 12 may be formed to a desired depth by controlling the curing conditions, which may consist of time and temperature.

As the trenches 12 formed by etching are given a surface roughness greater than that of the insulation substrate 3 due to the chemical reaction, etching is a method that provides an additional effect of surface improvement for increasing the conductive material filled in the trenches 12 and the insulation substrate 3.

While various methods may be used in applying the etchant 10 on the surface of the insulation substrate 3 in correspondence with the shape of the circuit patterns within a scope apparent to those skilled in the art, it is preferable to use inkjet printing. When using inkjet printing, CAD data on the pre-designed circuit patterns may be transmitted to an inkjet printing device to directly print the etchant 10, whereby no additional processes are necessary between the designing of the circuit patterns and the forming of the trenches 12 on the surface of the insulation substrate 3, and the overall process is simplified.

After forming the trenches 12 to a required depth, conductive material is filled into the trenches 12 to form the circuit patterns. While the conductive layer filled in the circuit patterns may be formed from any conductive material within a scope apparent to those skilled in the art, it is desirable that it be formed by sintering metal ink 20.

Metal ink 20 is an ink containing metal particles. It is filled in the trenches 12, after which drying and firing procedures are performed to form a conductive layer. Meanwhile, as in the case of the etchant 10 described above, it is desirable that the metal ink 20 also be applied in the trenches 12 by inkjet printing. In this case, a printed circuit board according to an embodiment of the invention is formed by a very simple process of printing the etchant 10 and the metal ink 20 on the surface of the insulation substrate 3 using inkjet printing.

To ensure an effective application of the metal ink 20 by inkjet printing, it is desirable that the metal ink 20 according to an embodiment of the invention contain metal particles of sizes in the nano scale, such as from 1 nm to 100 nm.

Meanwhile, as with conventional printed circuit boards, a printed circuit board according to an embodiment of the invention may use a polyimide substrate for the insulation substrate 3. However, as the properties of a polyimide substrate include its superior durability and corrosion-resistance, careful attention is required in selecting the etchant 10 for forming the trenches 12 according to an embodiment of present invention. That is, an etchant 10 for polyimide resin is used.

With a printed circuit board based on an embodiment of the invention, trenches 12 are formed beforehand at the positions where the circuit patterns are to be formed, and then conductive material is filled in the trenches 12 to form the circuit patterns, so that a thickness of the circuit patterns is obtained that corresponds to the depth of the trenches 12. Therefore, the depth of the trenches 12 is formed in correspondence to the required thickness of the circuit patterns, and when circuit patterns of 10 μm or greater are desired, the curing time or curing temperature of the etchant 10 is adjusted such that the trenches 12 are formed to have a depth of 10 μm or greater.

According to the present invention comprised as above, the production costs of printed circuit boards can greatly be reduced, since the processes of applying photoresist (PR), exposing, and developing can be eliminated to simplify the overall process, and the circuit patterns of printed circuit boards can be formed minutely and with precision with a fewer number of processes and less time.

Also, as trenches are formed directly by means of an etchant using inkjet printing equipment on the surface of the base material at positions where the circuit patterns are to be formed, and circuit patterns are formed by filling nano metal ink in the trenches in the same manner, circuit patterns can be obtained that have greater precision in terms of both dimensions and shape.

Further, since circuit patterns can be obtained of a thickness corresponding to the depth of the trenches by adjusting the curing conditions of the etchant, the problem in forming circuit patterns by directly printing nano metal ink on an insulation substrate, that a required thickness of the circuit patterns is not obtained, can be resolved.

While the spirit of the invention has been described in detail with reference to particular embodiments, the embodiments are for illustrative purposes only and do not limit the invention. It is to be appreciated that various changes and modifications may be made by those skilled in the art without departing from the spirit and scope of the present invention, as defined by the appended claims and their equivalents.

What is claimed is:

1. A method of forming circuit patterns on a printed circuit board, the method comprising:
(a) applying etchant on portions of an insulation substrate where circuit patterns are to be formed;
(b) curing the etchant by adjusting curing conditions;
(c) applying metal ink in the etched circuit patterns; and
(d) sintering the metal ink.

2. The method of claim 1, wherein the operation (a) or the operation (c) is performed by inkjet printing.

3. The method of claim 1, wherein the insulation substrate is a polyimide substrate.

4. The method of claim 3, wherein the etchant is an etchant for polyimide resin.

5. The method of claim 1, wherein the sintering conditions comprise temperature and time.

6. The method of claim 1, wherein the metal ink comprises metal particles of 1 μm to 100 nm in size.

7. A printed circuit board comprising:
an insulation substrate;
a trench formed on a surface of the insulation substrate in correspondence with a portion where a circuit pattern is to be formed; and
a conductive layer filled in the trench and forming the circuit pattern,
wherein the trench is formed by etching, and the conductive layer is formed by sintering metal ink.

8. The printed circuit board of claim 7, wherein the trench is formed by printing etchant on the insulation substrate by inkjet printing and afterwards curing the etchant by adjusting curing conditions.

9. The printed circuit board of claim 7, wherein the conductive layer is formed by filling metal ink in the trench by inkjet printing and afterwards drying and sintering.

10. The printed circuit board of claim 7, wherein the insulation substrate is a polyimide substrate.

11. The printed circuit board of claim 10, wherein the etchant is an etchant for polyimide resin.

12. The printed circuit board of claim 7, wherein the metal ink comprises metal particles of 1 nm to 100 nm in size.

13. The printed circuit board of claim 7, wherein the depth of the trench is greater than or equal to 10 μm and lower than or equal to the thickness of the insulation substrate.
